(19) United States
(12) Patent Application Publication
(10) Pub. No.: US 2005/0224882 A1
(43) Pub. Date: Oct. 13, 2005

(54) LOW TRIGGER VOLTAGE ESD NMOSFET TRIPLE-WELL CMOS DEVICES

(75) Inventors: Kiran V. Chatty, Williston, VT (US); Robert J. Gauthier JR., Hinesburg, VT (US); Mujahid Muhammad, Essex Junction, VT (US); Christopher S. Putnam, Hinesburg, VT (US)

Correspondence Address: CONNOLLY BOVE LODGE & HUTZ LLP;IBM MICROELECTRONICS DIVISION, 1990 M STREET NW, SUITE 800, WASHINGTON, DC, 20036-3425, US

(73) Assignee: INTERNATIONAL BUSINESS MACHINES CORPORATION, Armonk, NY (US)

(21) Appl. No.: 10/709,041

(22) Filed: Apr. 8, 2004

(51) Int. Cl. H01L 23/62

(52) U.S. Cl. 257/355

(57) ABSTRACT

An ESD NMOSFET, and a method for lowering a ESD NMOSFET trigger voltage. An ESD NMOSFET is configured in triple well CMOS architecture where the first well is separated from second and third wells by respective shallow well isolation regions. The first well is also separated from the substrate along the bottom by a conductive band region. A substrate contact is located outside of the first, second and third wells, and provides a current path during an ESD event from the first well. Source and drain regions are formed in the first well, to form an FET with the drain being connected to an I/O pad which is subject to an ESD event. A resistive path extends through an opening in the conductive band region to a substrate contact, providing an increased I/O pad to substrate resistance which decreases the trigger voltage for the ESD NMOSFET.

### BACKGROUND OF INVENTION

The present invention relates to the protection of integrated circuits against ESD voltage events. Specifically, a device for lowering the turn-on or trigger voltage of an ESD protection transistor is disclosed.

The progression of integrated circuit technology has led to the scaling of transistors to enable faster transistors operating at lower supply voltages. In CMOS applications, the faster transistors require the use of very thin gate oxides and shorter channel lengths in order to obtain higher drive currents. The gate oxide thickness, for instance, has decreased from approximately 5.0 nm in 0.25 um technology to approximately 1.5 nm in 90 nm technology, and is expected to decrease even further in future technologies. The thinner gate oxides are more susceptible to failure under random ESD voltages due to their smaller breakdown voltages.

The problem of ESD voltage events occurring on input/output pins to the integrated circuit has been addressed in many ways. Most common is the use of an ESD protection device connected to the input/output pad of an integrated circuit to safely discharge ESD currents to ground before they can damage any of the connected circuitry. ESD events may be generally characterized as Human Body Model (HBM), Charged Device Model (CDM) or Machine Model (MM). Different ESD models correspond to different current pulse waveforms and different peak currents.

One of the more common devices for protecting the integrated circuits from ESD events is the use of an NMOSFET, which, when connected to the input/output connection, discharges the current produced from an ESD event to ground. The NMOSFET based ESD protection device operates either as a lateral NPN Bipolar Junction Transistor (NPN BJT) or as a diode depending on the polarity of the ESD event. During a positive mode ESD event on the input/output pin to which the NMOSFET is connected, the NMOSFET device operates as a BJT to quickly dissipate the ESD current to ground. During a negative ESD event, where the potential on the input/output pin goes negative by a large voltage spike, the NMOSFET operates as a diode to discharge the ESD current to ground.

The smaller breakdown voltage of the thin gate oxides and the decreasing junction breakdown voltages in the state of the art CMOS devices require that the ESD protection devices turn-on and operate at voltages lower than the gate oxide or junction breakdown to enable adequate ESD protection.

A particular CMOS fabrication technique which has been used in the past implements CMOS devices in a triple well architecture. The triple well architecture allows individual devices to be constructed in P-wells that are effectively isolated from the substrate and neighboring circuits, enabling good noise isolation that is essential for noise sensitive analog circuits. The triple well technology also permits different power supply voltages to be applied to different regions of the chip. Further, the triple well architecture allows individual biasing of the substrate, without affecting the bias level of the neighboring devices.

The key requirements for ESD devices is a turn-on or trigger voltage which is smaller than the turn-on or trigger voltage of the other devices that are not used for ESD protection, such as NMOSFETs or PMOSFETs connected to an I/O pad. The ESD device should not turn on during normal operations of an I/O circuit, should provide a low resistance during the conducting state, and should have a high current handling capability.

NMOSFETs for ESD protection have previously been implemented in triple well CMOS architecture. These devices are fabricated as an NMOSFET within the isolated P-well of the triple well structure. In order to lower the trigger voltage of the ESD NMOSFET, it is known to increase the substrate resistance of the NMOSFET. Typically, the substrate resistance can be increased by increasing the distance of the substrate contact from the source/drain regions of the NMOSFET. The disadvantage of this approach is an increased ESD NMOSFET size. Increasing the P-well sheet resistance also increases the substrate resistance. However, the P-well sheet resistance is determined by the process technology and any change to the process to enable a higher sheet resistance for the ESD NMOSFETs would involve additional masking layers and/or additional processing steps and therefore additional expense. There are other circuit techniques to lower the trigger voltage of ESD NMOSFETs such as substrate pump circuits, but they would result in an increase in the size of the ESD device.

Accordingly, the present invention represents a solution to the problem of providing lower trigger voltage ESD NMOSFETs in a triple well CMOS architecture.

### SUMMARY OF INVENTION

An ESD NMOSFET is disclosed which is fabricated in triple well CMOS architecture. The ESD NMOSFET has a lower trigger voltage by virtue of the fact that a resistive path extending through the well containing the ESD NMOSFET, and terminating on a substrate contact outside of the well, increases the substrate resistance and lowers the ESD NMOSFET trigger voltage. The resistive path is formed by virtue of a segment or space formed in a conductive band region which separates the isolated P-well from the substrate. Substrate material extends through the spacing or segment forming a higher resistive path from the device to the substrate contact. The result of the higher resistive path effectively increases the substrate resistance without changing the space occupied by the ESD NMOSFET, and lowers the trigger voltage. Depending on the details of the ESD NMOSFET design, this may enable the use of a smaller drain region, reducing the total area requirement for the device.

### BRIEF DESCRIPTION OF DRAWINGS

FIG. 1 is an illustration of the use of ESD-NMOSFETs for protecting circuits connected to an I/O pad of an integrated circuit.

FIG. 2A is a prior art ESD NMOSFET in a dual well CMOS architecture.

FIG. 2B is a prior art NMOSFET in a triple well CMOS architecture.

FIG. 3 illustrates the current-voltage characteristic of the ESD NMOSFET under an ESD condition.

FIG. 4 illustrates a preferred embodiment of the invention where an ESD NMOSFET is implemented with a lower turn-on voltage in a triple well CMOS architecture.

FIG. 5 illustrates the current-voltage characteristics of the proposed ESD NMOSFET of FIG. 4 derived from a device simulation, and the current-voltage characteristic of a prior art ESD NMOSFET.

### DETAILED DESCRIPTION

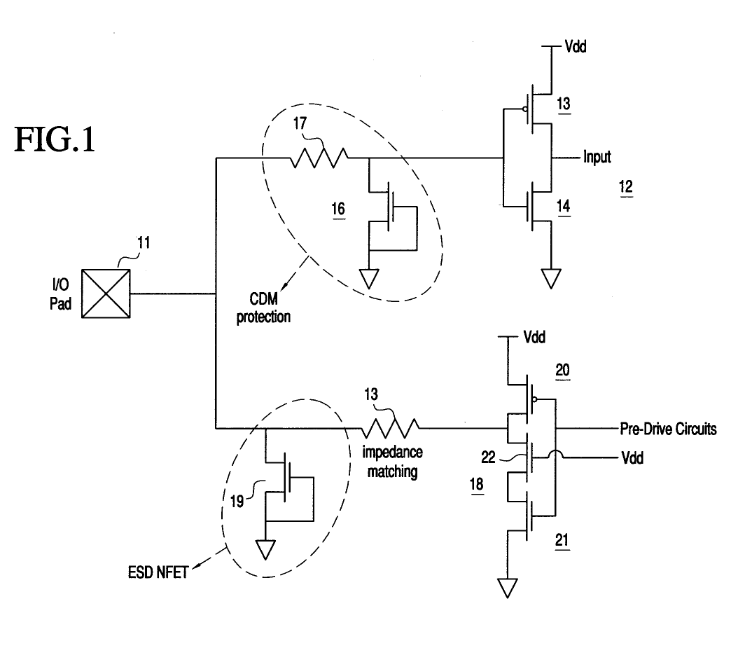

FIG. 1 is the general illustration of the concept of ESD protection. An Electrostatic Discharge (ESD) may be experienced on any of the input/output pads 11 of a semiconductor circuit. These high voltage events, while brief in duration, can be catastrophic to the connected circuitry. Accordingly, each I/O pad must have ESD protection along with the power supply terminals, VDD and ground (GND), to avoid the catastrophic effects of an electrostatic discharge on terminals external to the circuit.

The ESD protection includes a first NMOSFET connected across an input circuit 12 connected to an I/O pad 11. The input circuit receives a signal from pad 11, through a resistive element 17. The input circuit 12 comprises conventional PMOSFET and NMOSFET devices 13, 14. The protection afforded by the ESD NMOSFET 16 and ESD NMOSFET 19 diverts current produced from an ESD potential appearing on I/O pad 11 to ground before the voltage can reach a level which damages the gate oxides of transistors 13 and 14. ESD NMOSFET 16 is shown as generally providing protection from a CDM type ESD event. Similarly, for the drive circuit 18, ESD NMOSFET 19 limits any increase in voltage which would appear on the source connections of the PMOSFET 20 and drain connections of NMOSFETs 21, 22 of output drive circuit 18. Because of the presence of series resistance 17, ESD NMOSFET 19 dissipates most of the current produced in an ESD event.

During a positive mode ESD event when the potential on I/O pad 11 is positive, ESD NMOSFETs 16, 19 act as lateral NPN bipolar transistors for discharging current to ground. During a negative mode ESD event, the ESD NMOSFETs 16, 19 act as a diode to ground and also discharge the current to ground.

The turn-on or trigger voltage of the ESD device should be smaller than the turn-on or trigger voltage of the output circuit transistors or the breakdown voltage of the gate oxides of the input circuit transistors which are connected to the I/O pad. During normal operation, the ESD transistors are turned off and do not interfere with signals appearing on the I/O pad 11. During a conduction state, wherein the ESD device has been triggered into conduction due to an ESD event, the on resistance for the device is preferably low to rapidly dissipate any such ESD event. Currents can be high at least on an instantaneous basis, and the ESD devices must have the ability to carry high currents for a brief period of time.

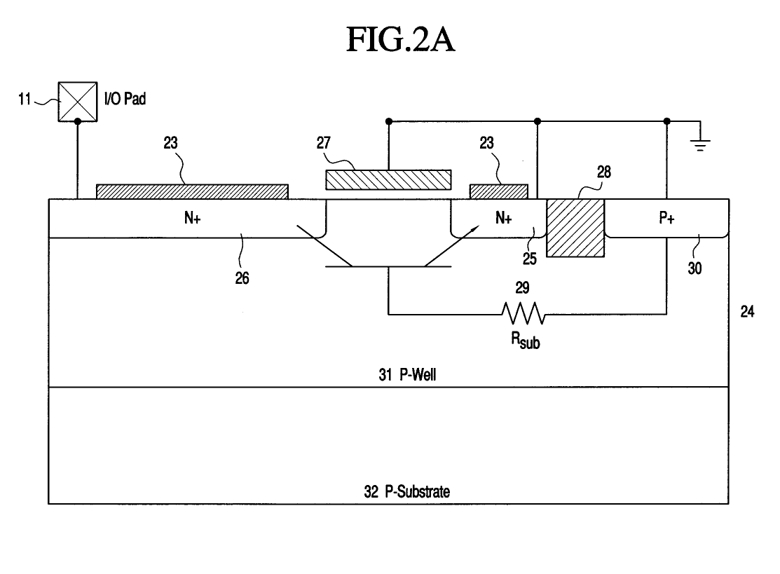

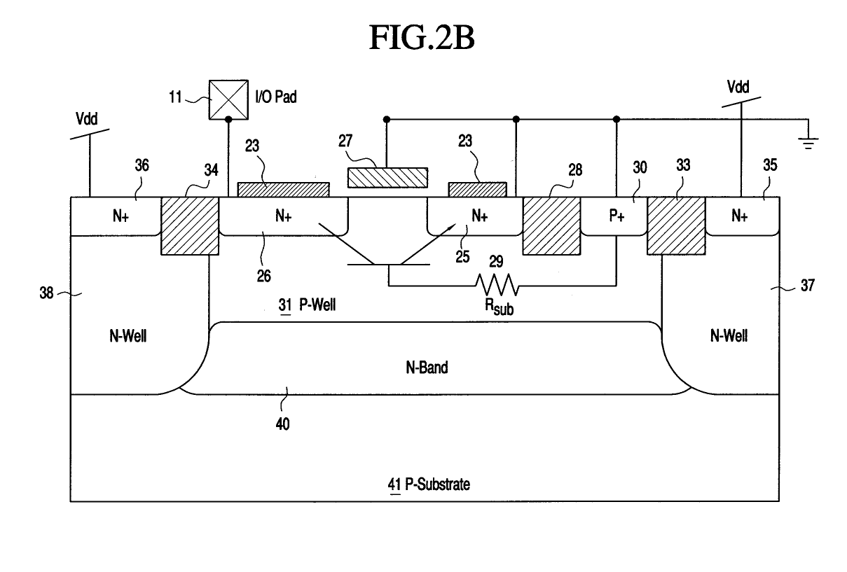

The ESD NMOSFET in accordance with the prior art may be configured in a CMOS silicon substrate as shown in FIG. 2A which illustrates how the prior art ESD NMOSFET 24 operates as a BJT during a high positive mode ESD event. The ESD NMOSFET 24 includes a drain 26 and source 25 formed within a P-well in a dual well CMOS architecture formed on p-substrate 32. A gate connection 27 is connected to the substrate contact 30 which also serves as a common terminal. A trench isolation region 28 is formed to separate the source, drain and substrate diffusions. The silicide blocking regions 23 on the drain 26 and source 25 are present to provide adequate current ballasting during an ESD event to enable a high current handling capability. The silicide blocking regions are typically formed from a silicide nitride layer.

During the ESD event, a BJT is triggered on due to a high positive potential on drain 26. The substrate resistance, R_{sub} representing the effective resistance between the channel region of the NMOSFET and substrate contact 30, develops a forward biasing voltage to effectively turn on the BJT for dissipating the ESD voltage on I/O pad 11. During a negative ESD event, the drain 26 effectively becomes a diode with the substrate and dissipates current through the substrate contact 30.

During a positive mode ESD event, N+ drain/substrate junction breaks down and results in the avalanche generation of carriers (electrons and holes). The holes are collected by the substrate raising the substrate potential due to the IR drop (V_{sub}=I_{sub}*R_{sub}) which eventually forward biases the source/substrate junction. The result is that the source 26, substrate 30, and drain 25 act as an NPN BJT dissipating the ESD voltage. A silicide blocked region 23 on the source 25 and drain 26 diffusions provides ballasting resistance to ensure a uniform flow of discharge current.

FIG. 2B represents the implementation of an ESD NMOSFET in a triple well CMOS architecture. The additional N-Band 40 constitutes a n-type doped region which in combination with the N-Wells 37 and 38 isolates the P-well 31 from the substrate 41. As can be seen from FIG. 2B, the triple well architecture of the prior art is similar to the dual well architecture, with the exception of the additional N-Band 40, and N-wells 37 and 38. N-well 37 and 38 are connected in the embodiment shown to a source of positive potential VDD. Additionally, two other isolation regions 33 and 34 are provided to provide isolation for the N-wells 37 and 38.

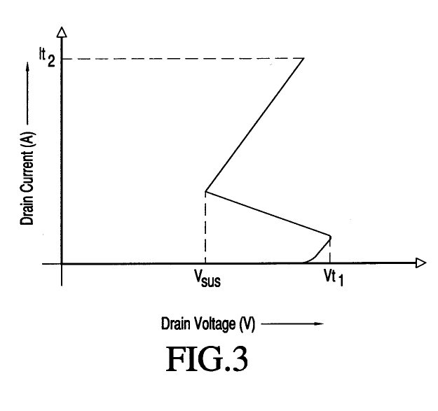

The typical voltage/current characteristics for a positive ESD event are shown in FIG. 3. The voltage on the drain of the device represents the potential due to an ESD event when the gate 27 voltage is zero. When the potential reaches the trigger voltage or Vₜ₁ the device is triggered into a conduction mode. The voltage at the drain begins to discharge due to the conduction of the bipolar transistor until it reaches a sustaining voltage (V_{SUS}. From then on, current is discharged through the device, and the potential begins to rise again due to the drain diffusion resistance. In the case of CMOS technology where oxide thicknesses are becoming increasingly smaller, devices are more susceptible to damage due to an ESD event. Consequently, it is necessary to have a lower trigger voltage (Vₜ₁ to provide adequate ESD protection.

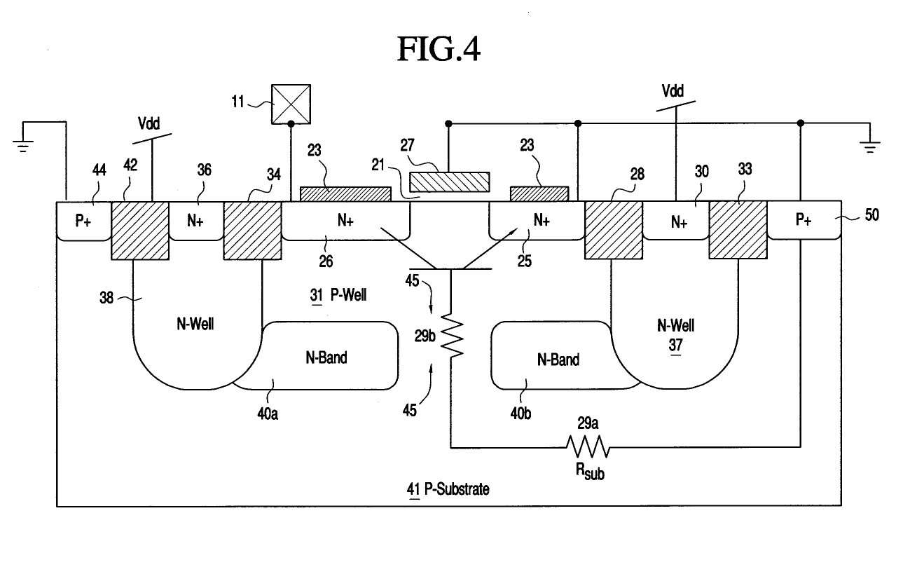

The proposed invention will permit the attainment of a lower trigger voltage (Vₜ₁) for the ESD NMOSFET. FIG. 4 shows a preferred embodiment of the invention implemented in a triple well CMOS architecture. ESD NMOSFET transistor has drain 26 and source 25 diffusion regions formed within a P-well 31. Source and drain silicide blocked regions 23 are formed over the source and drain diffusion regions 25 and 26. A gate connection 27 is formed over a thin oxide region 21 to provide a conventional gate structure for the device.

N-well contacts 30, 36, source 25, drain 26 and substrate contacts 44 and 50 are isolated from each other using shallow trench isolation structures 28, 33, 34 and 42. The bottom of the P-well 31 is generally separated from the substrate 41 with a segmented N-band conductive band region 40a, 40b. N-well 38 and N-well 37 are connected through contact 36, 30 to VDD. As shown in the figure, an opening 45 is provided between N-band segments 40a and 40b through which P-well 31 is electrically connected to the substrate 41. The result is a resistive path from P-well 31, represented as 29a and 29b, to a substrate contact 44 and 50 located outside of the N-wells.

The effect of this structure is to provide an increased resistive path from the P-well 31 to substrate contacts 44 and 50. The distance between substrate contact 44 and 50 and P-well region 31 through the gap in N-band region 40 and the lighter doping of the substrate 41 increases the substrate resistance. Accordingly, the ESD NMOSFET triggers at a lower voltage compared to prior art NMOSFETs connected to an I/O pad and effectively protects them. The lower trigger voltage of the ESD NMOSFET permits a smaller drain silicide block region 23, which in turn reduces the area requirement. Based on simulation results for the foregoing structure, the area reduction for the foregoing structure is approximately 25%.

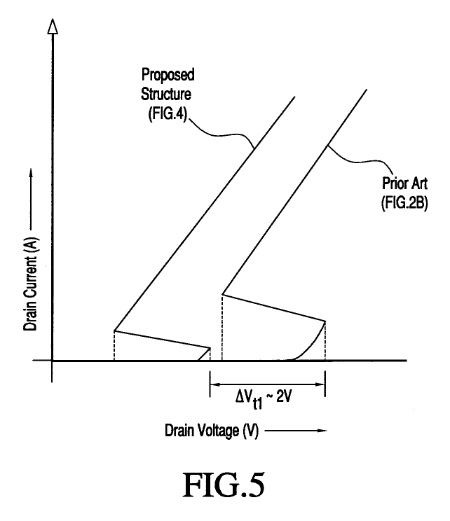

The drain current vs. drain voltage characteristics illustrated in FIG. 5 shows the effect of the resulting architecture on the ESD NMOSFET performance. The illustrations are based on simulation results of the proposed ESD NMOSFETs on a tool used in the integrated circuit and device design art. The figure shows the drain current vs. drain voltage for the conventional ESD NMOSFET of FIG. 2, in a triple well architecture according to the prior art. As can be seen, a lower trigger voltage Vₜ₁ is obtained for the device of FIG. 4, wherein conduction occurs at approximately 2 volts less than that for the conventional ESD NMOSFETS. hus, the preferred embodiment provides for a lower turn-on voltage Vₜ₁ as well as a lower trigger current due to the larger substrate resistance R_{SUB} obtained with the embodiment of FIG. 4

Thus, by using the modified triple well architecture of FIG. 4, wherein the substrate resistance for the ESD NMOSFET is increased, and significant performance improvements are realized for the device.

The foregoing description of the invention illustrates and describes the present invention. Additionally, the disclosure shows and describes only the preferred embodiments of the invention in the context of a low trigger voltage ESD NMOSFET triple-well CMOS technology, but, as mentioned above, it is to be understood that the invention is capable of use in various other combinations, modifications, and environments and is capable of changes or modifications within the scope of the inventive concept as expressed herein, commensurate with the above teachings and/or the skill or knowledge of the relevant art. The embodiments described hereinabove are further intended to explain best modes known of practicing the invention and to enable others skilled in the art to utilize the invention in such, or other, embodiments and with the various modifications required by the particular applications or uses of the invention. Accordingly, the description is not intended to limit the invention to the form or application disclosed herein. Also, it is intended that the appended claims be construed to include alternative embodiments.

1. An ESD NMOSFET with a lower trigger voltage comprising:
a substrate having first, second and third wells formed in said substrate, and separated by shallow well isolation regions, said first and third wells connected along a bottom thereof with a conductive band region generally separating the bottom of said second well from said substrate;
a source and drain region in said second well forming an FET, said drain being connected to an I/O pad for protecting said pad against an ESD event; and
a path of substrate material extending through an opening in said conductive band region, to increase the substrate resistance in the path of the current which flows through said I/O pad to a substrate contact and drain during an ESD event.

2. An ESD NMOSFET according to claim 1 wherein said substrate has a contact which is outside of said first, second and third wells.

3. An ESD NMOSFET according to claim 1 wherein said first and third wells are N-wells and said conductive band region comprises a semiconductor region which is N doped.

4. An ESD NMOSFET according to claim 3 wherein said conductive band region is segmented forming said resistive path to said substrate.

5. The ESD NMOSFET according to claim 1 wherein said FET has a gate connection and source connected to said substrate contact.

6. The ESD NMOSFET according to claim 1 wherein said drain is connected through a matching impedance to said I/O pad to provide a signal from a circuit on said substrate to said I/O pad.

7. A method for decreasing the trigger voltage of an ESD NMOSFET comprising:
locating said ESD NMOSFET in a well of a triple well CMOS structure, and connecting said ESD NFET to an I/O pad; and
providing a resistive path from said first well to a substrate contact located outside of said wells, whereby the trigger voltage of the said ESD NMOSFET is reduced due to said resistive path between said substrate contact and said I/O pad.

8. The method according to claim 7 wherein said resistive path is an opening in said well to form a connection between said NMOSFET and said substrate contact.

9. The method according to claim 7 wherein said well is an P-well with an N-band of N doped semiconductor material which separates said N-well from said substrate, and which includes an opening forming said resistive path.

10. The method according to claim 7 wherein said ESD NMOSFET further comprising connecting a gate connection and a source of said NMOSFET to said substrate contact.

11. The method according to claim 7 wherein a second and third well of said triple well structure are N-Wells, and one of said N-wells is connected to said substrate contact.

12. The method according to claim 7 further comprising connecting a gate of said Nto said substrate contact.

13. An ESD NMOSFET with a lower trigger voltage comprising:substrate having first, second and third wells formed in said substrate, said first well comprising a P-well separated from second and third N-Wells by shallow well isolation regions, said first well separated from said substrate along a bottom thereof with a conductive band region;substrate contact outside of said first, second and third wells;
a source and drain region in said P Well forming an FET, said drain being connected to an I/O pad for protecting said pad against an ESD event; and
a resistive path extending through an opening in said conductive band region to said substrate contact, said resistive path decreasing the trigger voltage for said FET.

14. The ESD NMOSFET according to claim 13 wherein said FET source and gate are connected to substrate contact.

15. The ESD NMOSFET according to claim 13 wherein said source is connected to said substrate contact.
